(19) United States
(12) Patent Application Publication
(10) Pub. No.: US 2007/0298525 A1
(43) Pub. Date: Dec. 27, 2007

(54) Integrated microelectronic package stress sensor

(76) Inventors: Nachiket R. Raravikar, Chandler, AZ (US); Amram Eitan, Scottsdale, AZ (US); Neha Patel, Chandler, AZ (US)

Correspondence Address: TROP PRUNER & HU, PC, 1616 S. VOSS ROAD, SUITE 750, HOUSTON, TX, 77057-2631, US

(21) Appl. No.: 11/475,799

(22) Filed: Jun. 27, 2006

(51) Int. Cl. H01L 21/66; G01R 31/26

(52) U.S. Cl. 438/14

(57) ABSTRACT

Stress in microelectronic integrated circuit packages may be measured in situ using carbon nanotube networks. An array of carbon nanotubes strung between upstanding structures may be used to measure the local stress in two dimensions. Because of the characteristics of the carbon nanotubes, a highly accurate stress measurement may be achieved. In some cases, the carbon nanotubes and the upstanding structures may be secured to a substrate that is subsequently attached within a microelectronic package. In other cases, the nanotube structures may be formed directly onto integrated circuit dice.

### BACKGROUND

This relates generally to measuring stress in microelectronic packages.

Stress arises in microelectronic packages from a number of sources. Heating and cooling may result in local stresses within the package. Likewise, mechanical stresses may be applied to the package from the external environment. For example, in packages with pins, stresses may be applied to the package through the pins.

As a result of stresses applied to microelectronic packages, failures may occur. Die cracks may arise due to local stresses. Stresses may affect the electrical functionality of the die with that actually resulting in cracks or other physical distress. For example, the functional robustness of a flash memory die may be influenced by local stresses on that die.

On die stress measurements may be taken using metallic rosette structures. These sensors may involve sputter deposited rosette sensor lines that undergo change in resistance as a function of stress. However, the deposited metals may suffer from oxidation and corrosion during processing and during package operation which make them less reliable in the long term. Also, current techniques for metal deposition do not give very high spatial resolution for a stress measurement.

### BRIEF DESCRIPTION OF THE DRAWINGS

FIG. 1 is an enlarged, top plan view of one embodiment of the present invention;

FIG. 2 is a cross-sectional view taken generally along the line 2-2 in FIG. 1;

FIG. 3 is a top plan view corresponding to FIG. 1 at a subsequent stage of manufacture in accordance with one embodiment of the present invention;

FIG. 4 is a cross-sectional view taken generally along the line 4-4 in FIG. 3;

FIG. 5 is a top plan view corresponding to FIG. 4 at a subsequent stage of manufacture in accordance with one embodiment of the present invention;

FIG. 6 is a cross-sectional view taken generally along the line 6-6 in the structure of FIG. 5 in accordance with one embodiment of the present invention;

FIG. 7 is a cross-sectional view taken generally along the line 6-6 in accordance with still another embodiment of the present invention; and

FIG. 8 is a system depiction in accordance with one embodiment of the present invention.

### DETAILED DESCRIPTION

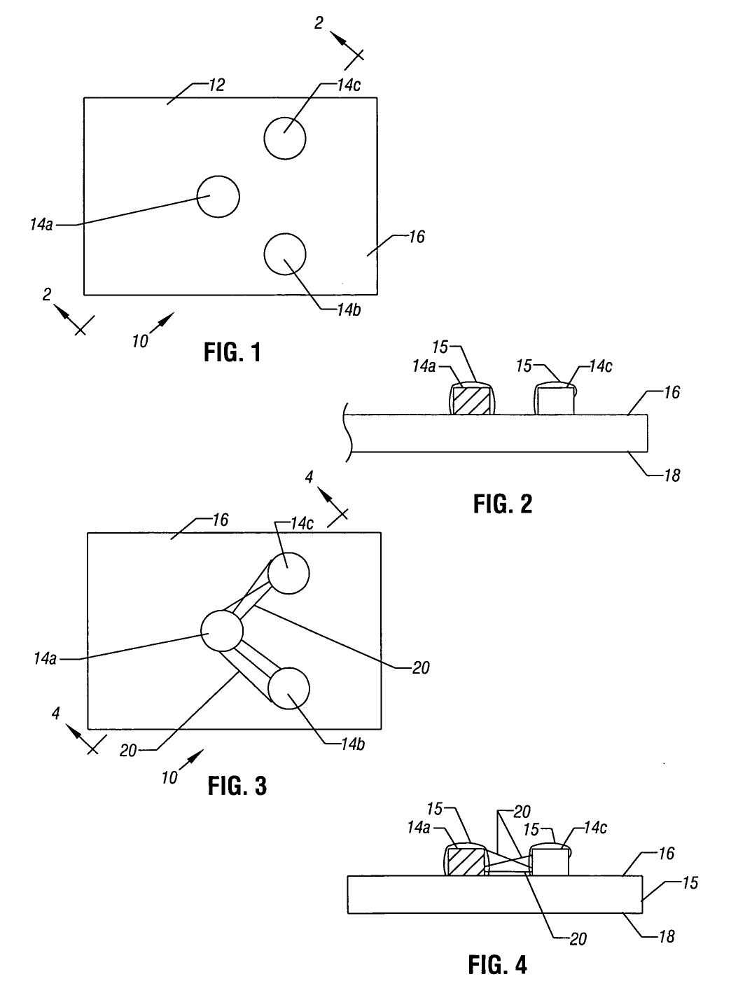

Referring to FIGS. 1 and 2, a substrate 10 may be a semiconductor die having a back side 16 in one embodiment. The back side 16 of a semiconductor die is generally unused for electronic features. The opposite side, or front side 18 of the substrate 10, generally has the integrated circuit features that provide electrical functions and performance in an embodiment that is a semiconductor die.

In accordance with one embodiment of the present invention, a plurality of metallic upstanding structures 14 (i.e., structures 14a, 14b, and 14c) may be defined. These structures 14 may be made of material suitable for the growth of bridge-like, single walled carbon nanotubes. Specifically, in some embodiments of the present invention, prior to the formation of the electronic features on the opposite side of the substrate 10, the upstanding structures 14 may be formed on the back side 16.

In some embodiments of the present invention, the structures 14 may be formed directly on the substrate 10. The structures 14 may include pillars in one embodiment of the present invention covered by metal catalyst 15 such as iron, cobalt, or nickel. As an example, the structures 14 may be of a height of about a micron. The structures 14 may be formed, for example, by glancing angled deposition methods. By controlling the substrate 10 rotational motion, including both its angle and velocity, the structures 14 height can be controlled. Although different metal catalysts may be utilized, nickel may be preferred because it may offer lower contact resistance with the nanotubes to be formed subsequently.

Referring to FIG. 2, the structures 14 are upstanding and may be formed on the back side 16 of the substrate 10. The substrate 10 also includes a front side 18 which is not yet formed, in one embodiment of the present invention, where the substrate 10 is a semiconductor die. In addition, the substrate 10 may, in fact, be a ceramic substrate, such as a silica substrate, which, in some embodiments, is thereafter adhesively secured to a semiconductor die in an appropriate location for stress measurement, as will be described hereinafter.

Carbon nanotubes 20 may then be grown so as to bridge between the structures 14a, 14b, and 14c. In one embodiment, gas phase chemical vapor deposition may be used to grow the carbon nanotubes. In one embodiment of the present invention, methane may be used as a source of carbon for the growth of carbon nanotubes. As a result, the nanotubes extend from one upstanding structure 14 to another. Argon gas may be supplied during the deposition of the carbon nanotubes to reduce oxidation. A pressure of about 500 Torr and a furnace temperature of 800 to 950° C. in a methane environment may be utilized in one embodiment.

In one embodiment, the structures 14a and 14c are reasonably proximate, as are the structures 14a and 14b. However, the structures 14b and 14c are spaced sufficiently far apart that carbon nanotubes are not formed between the structures 14b and 14c. For example, in one embodiment of the present invention, a line through the center line of the structures 14a and 14c intersects a line through the center line of the structures 14b and 14a at approximately right angles. In one embodiment, only the structures 14a and 14c, as well as the structures 14a and 14b, are close enough to form bridging carbon nanotubes 20 (FIG. 3).

The structures 14 may be formed, in one embodiment, by depositing a catalyst 15 over a pillar pre-formed on a substrate. For example, the pillars may be silicon or silicon dioxide pillars. The pillars may be formed, for example, by growing or depositing the pillar material, masking, and etching to form the pillars in the desired arrangement. In some embodiments, at least two of the pillars may be aligned with a crystallographic plane of substrate 10 (in the embodiment where the substrate is a crystalline semiconductor).

During the catalyst film deposition, the substrate 10 may be tilted twice about plus and minus 45 degrees to spread the catalyst 15 over the structures 14. The carbon nanotubes 20 later form on the sidewall of structures 14 where the catalyst 15 is present. The catalyst 15 may not completely cover the pillars in some cases.

In some embodiments, an array of pillars (not shown) may be grown, but only some of the pillars may be activated with catalyst. For example, only three pillars may be activated with catalyst so that right angled arrays of carbon nanotubes are formed. The selective activation may be accomplished using masks or selective catalyst deposition. While cylindrically shaped structures 14 are depicted, other shapes may also be used.

As shown in FIGS. 3 and 4, the nanotubes 20 may grow generally horizontally from the top to bottom along the structures 14a, 14b, and 14c. They span as bridges over the substrate 10.

Because of the angulation between the sets of carbon nanotubes secured between structures 14a and 14c versus those secured between structures 14a and 14b, strain in the nanotubes can be measured in two dimensions. For example, the two sets of carbon nanotubes may be perpendicular to one another. The strain in the nanotubes 20 correspond to the strain in a device under test secured to the nanotubes 20 and structures 14.

In some embodiments, and particularly in embodiments in which the structures 14 are formed directly on a silicon die, the substrate 10 may subsequently be thinned down so that its own thickness does not contribute to changes in stress of the die whose stress is being measured. A thinned down substrate may also be glued onto any polymeric or ceramic surface.

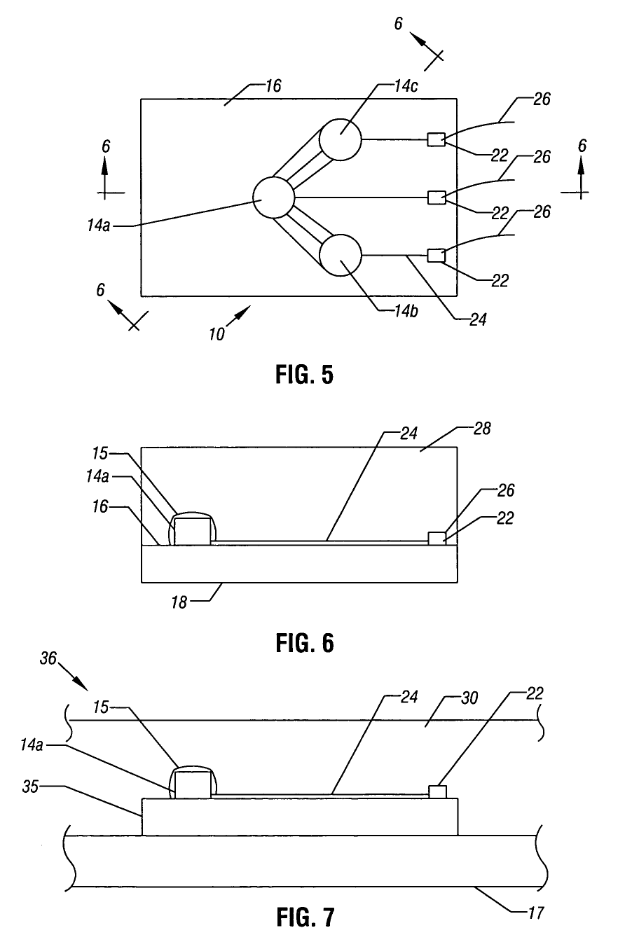

The nanotubes 20 may be electrically coupled to an external strain gauge (not shown) using metal lines, as shown in FIG. 5. Particularly, metal lines 24 may connect each structure 14 to a pad 22. From the pad 22, electrical connections 26 may be made to a strain gauge. The metal lines 24 and the pads 22 may be printed using conventional processes such as screen printing or plating. For two probe measurements, one electrical connection 26 may be bonded to each metal pad 22 with two wires to the central metal pad. For four probe measurements, twice as many wires may be bonded to each metal pad 22.

The wire or electrical connection 26 may be connected to a strain gauge. When the nanotubes are strained, a voltage change across the nanotubes is proportional to the strain experienced by the nanotubes.

In order to measure the strain on a semiconductor die, the nanotubes 20, shown in FIG. 5, may be grown on the back side of a die in one embodiment. The die then undergoes the subsequent, conventional circuit fabrication steps on the front side. The stress that causes die warpage can be measured in terms of the change in resistance of the nanotubes 20.

As indicated in FIG. 6, stress in the die attach may also be measured. The nanotubes 20 may be prepared on the back side of a die, using a tall pillar pattern such as one which uses the staples secured to a substrate. By “tall,” it is intended to refer to structures 14 having a height on the order of about 0.7 centimeters. Subsequently, the nanotubes are grown and the metallization is carried out.

Other structures 14 may also be utilized to grow bridge-like carbon nanotubes, including telephone pole and soccer goal oriented office staples. Literally, upstanding office staples may be utilized by securing them to silicon wafers using an appropriate adhesive such as carbon tape. The staples may have their points upstanding (“telephone poles”) or inverted (“soccer goal”) and extending into the substrate.

Then, carbon nanotubes may be grown using chemical vapor deposition and a furnace at 1373 Kelvin under about 100 mTorr vacuum. To 0.02 g/ml solution of ferrocene in 10 milliliters of hexane, two volume percent thiophene is added. The hexane may act as the source of carbon and the ferrocene acts as a catalyst for gas diffusion formation of carbon nanotubes. The solution may be heated to 150° C. and then introduced into a horizontal quartz tube furnace at an average rate of about 0.1 milliliters per minute for ten minutes. Thiophene is known to promote the formation of single-walled carbon nanotubes in H₂ atmosphere, whereas multi-walled carbon nanotubes are found to grow predominantly in the absence of H₂ atmosphere. Single-walled carbon nanotubes or multi-walled carbon nanotubes can be used by controlling the nanotube growth conditions via controlling the H₂ concentration in the furnace [No H₂ atmosphere will give multi-walled carbon nanotubes, whereas H₂ atmosphere may promote the single-walled carbon nanotube growth]. Although the recipe and numbers recited above are recommended to grow carbon nanotubes, the growth conditions are not necessarily limited to this recipe or these numbers, but rather is inclusive of those.

Then the whole die, including the nanotubes 20, may be coated with the die attach 28, followed by the die attach cure. Stress changes during the cure process may be measured by various nanotubes 20. The structure 14 height can be controlled to a few microns, such as 10 to 15 microns, so that the structure is less than about 25 microns in total height.

Referring next to FIG. 7, stress in the underfill or mold compound 30 may also be measured. The networks of carbon nanotubes 20 may be deposited or transferred onto microelectronic substrates which are typically organic. The underfill or mold compound flow and cure process may be carried out and changes in the resistance of the nanotubes are measured. In this case, the height of the structures 14 can be in the range of 15 to 20 microns because the total available height is about 45 microns.

An organic or other substrate 17 may have a die 35 secured thereto which includes structures 14, pads 22, and metal lines 24. The mold compound 30 may then be added over the top to form a semiconductor package 36.

In some embodiments, the nanotubes 20 may be highly accurate stress indicators. Of course, a stress indicator is correspondingly also a strain indicator. Because they have anisotropic characteristics in the length dimension and have very small dimensions transversely to the length dimension, high special resolutions may be obtained with carbon nanotubes. For example, the carbon nanotubes may be 1 to over 10 microns in length and less than 2 to 30 nanometers in diameter.

Because they tend to be atomically relatively perfect and chemically stable, carbon nanotubes can be more reliable as sensors than metallic structures of the same dimensions. Moreover, due to their anisotropic nature, nanotubes can potentially measure the stress tensors on the die. In some embodiments, the state of stresses, at locations that are separated by distances as small as a few microns to a few hundred nanometers, may be measured. In some cases, spatial resolution of a half micron may be possible.

The nanotube 20 to metal structure 14 contact resistance can be improved using various strategies. In one embodiment, electron beam irradiation at the nanotube 20/structure 14 junction may be used. As another alternative, small dots of solder may be deposited on the structure 14/nanotube 20 joint, followed by reflow.

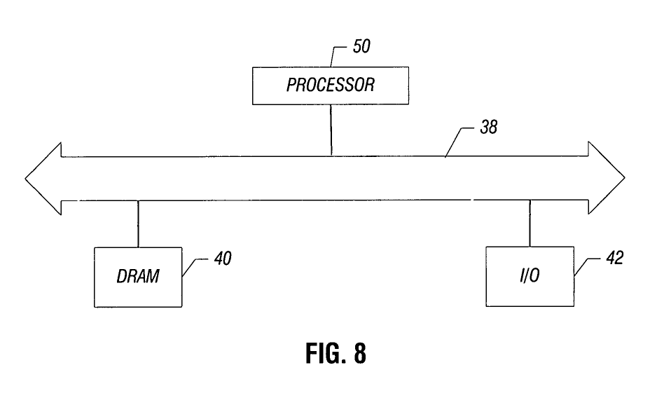

Referring to FIG. 8, a resulting microelectronic package may include a processor 50 in one embodiment. The processor 50 may be provided in a system that includes a system memory such as a dynamic random access memory (DRAM) 40 and an input/output device 42, all coupled by a bus 38. For example, the input/output device may be a mouse, a keyboard, a display, or any of a variety of such devices. The processor 50, in the package 36, may be subject to having its internal stresses measured using the techniques described herein.

As a result, the effect of stress on its operation may be monitored before the die is sold, as well as after the die is sold, in some cases. All that is necessary, in some embodiments, to record the stress is to attach a measuring apparatus to the nanotubes 20 via the pads 22. However, it may also be possible to measure the stress “on die,” for example, using circuitry formed on the die front side.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
using carbon nanotubes to measure stress on a microelectronic integrated circuit.

2. The method of claim 1 including using carbon nanotubes to measure stress on a semiconductor integrated circuit die.

3. The method of claim 2 including forming carbon nanotubes attached to said die.

4. The method of claim 3 including forming upstanding structures on said die and growing said carbon nanotubes between said structures.

5. The method of claim 3 including forming carbon nanotubes on upstanding structures over a substrate and securing said substrate to an integrated circuit die.

6. The method of claim 1 including using carbon nanotubes to measure stress in a die attach of a semiconductor package.

7. The method of claim 1 including using carbon nanotubes to measure stress in a compound surrounding an integrated circuit die.

8. The method of claim 1 including forming three upstanding structures on a substrate and growing carbon nanotubes between said structures.

9. The method of claim 9 including growing two arrays of carbon nanotubes between three upstanding structures such that one array is generally transverse to the other of said arrays.

10. The method of claim 9 including providing metallizations to contact said nanotubes.

11. A packaged integrated circuit comprising:
a substrate;
a set of three upstanding structures formed on said substrate;
carbon nanotubes bridging said structures; and
electrical connections to enable strain on said carbon nanotubes to be measured.

12. The circuit of claim 11 wherein said structures are formed directly on a substrate and said substrate is a semiconductor die.

13. The circuit of claim 12 wherein said structures support horizontally disposed sets of carbon nanotubes, one set bridging between a first two of said structures and another set bridging between another two of said structures.

14. The circuit of claim 13 wherein said carbon nanotubes of one set are generally perpendicular to carbon nanotubes of the other set.

15. The circuit of claim 14 wherein said structures are formed on said substrate and are covered by a catalyst.

16. The circuit of claim 15 wherein said catalyst is capable of encouraging growth of a carbon nanotube.

17. The circuit of claim 16 including a metallization electrically coupled to said carbon nanotubes, said metallization to be coupled to a strain gauge.

18. The circuit of claim 11 wherein said substrate is a semiconductor die and said structures are formed on the back side of said die.

19. The circuit of claim 11 wherein said circuit is covered by a die attach material and said carbon nanotubes are adapted to measure stress in said die attach material.

20. The circuit of claim 11 including fill material and said carbon nanotubes to measure strain in said fill material.

21. An integrated circuit die comprising:
a set of three upstanding structures formed on said die; and
a plurality of carbon nanotubes extending between said structures, one set of carbon nanotubes being generally perpendicular to another set of carbon nanotubes.

22. The die of claim 21 wherein electronic features are defined on one side of said die and said structures are formed on the back side of said die opposite said one side.

23. The die of claim 21 wherein said structures are formed of a non-conductive material and a conductive material is deposited over said structures.

24. The die of claim 23 wherein said conductive material is a catalyst to encourage the growth of carbon nanotubes.

25. A system comprising:
a processor;
a dynamic random access memory coupled to said processor; and
a package for said processor, said package including a die, said die including three upstanding structures formed on said die, carbon nanotubes spanning between said structures.

26. The system of claim 25 wherein said structures are formed directly on said die.

27. The system of claim 26 wherein said carbon nanotubes are arranged horizontally between adjacent upstanding structures.

28. The system of claim 27 including two sets of perpendicular carbon nanotubes.

29. The system of claim 28 wherein said structures are covered by a catalyst to encourage the growth of carbon nanotubes.

30. The system of claim 29 including a metallization to allow a change of voltage across said carbon nanotubes to be measured to determine strain in said carbon nanotubes and thereby strain in said die.
